(19) United States
(12) Patent Application Publication
(10) Pub. No.: US 2004/0035353 A1
(43) Pub. Date: Feb. 26, 2004

(54) Manufacturing of organized molecular monolayers and adapted substrate

(76) Inventors: Pierre Terech, Saint-Cassien (FR); Francois Rieutord, Saint-Egreve (FR); Bernd Struth, Fontaine (FR)

Correspondence Address: DUANE MORRIS LLP, 100 COLLEGE ROAD WEST, SUITE 100, PRINCETON, NJ, 08540-6604, US

(21) Appl. No.: 10/445,543

(22) Filed: May 27, 2003

(30) Foreign Application Priority Data
May 28, 2002 (FR) 02/06526

(51) Int. Cl. C30B 33/06

(52) U.S. Cl. 117/1

(57) ABSTRACT

A substrate adapted to the chemical grafting of an ordered molecular monolayer, formed of a crystal, the lattice of which comprises a hydroxyl group, this crystal being cleavable so that hydroxyl groups appear in the cleavage plane, and belonging to the group comprising topaz and diaspore.

### BACKGROUND OF THE INVENTION

1. Field of the Invention

The present invention relates to the forming of organic, organometallic, or inorganic monolayers grafted on a substrate, exhibiting a regular molecular organization over a significant surface area.

2. Discussion of the Related Art

Since a few years, monolayers (or monolayer stackings) of simple or complex molecules are desired to be deposited on substrates. Various applications of such monolayers have already been described in the art, such as sensors, semiconductors, waveguides, etc.

However, up to now, there has been a major obstacle, which is that perfectly well ordered or single-crystal monolayers cannot be formed over relatively large surface areas. The best substrates currently provided to deposit such monolayers are materials such as gold, with which, for example, alkanethiol molecules combine. However, in practice, perfectly well-ordered monolayers without grain boundaries over distances greater than approximately 30 nm (surface areas greater than approximately 1000 nm²) cannot be obtained. It has also been attempter to have molecules catch on silicon substrates. However, in this technique, the presence of a very thin amorphous oxide layer does not enable imposing the crystalline order of the silicon substrate to the organic layer.

### DESCRIPTION OF THE INVENTION

Thus, an object of the present invention is to provide a new type of substrate enabling simple and ordered grafting over a significant surface area, of organic, organometallic, or inorganic molecules in a monolayer.

To achieve this object, the present invention provides using single-crystal mineral substrates, the chemical notation of which comprises hydroxyl groups (OH) and having a cleavage plane, planar over a significant surface area, comprising hydroxyl groups accessible at the surface. Among these substrates, crystals having their mesh parameters, and more specifically the distance between hydroxyl groups, compatible with the bulk of the molecules to be grafted, will be selected.

The molecules to be grafted will for example be aliphatic chains such as alkane chains or aliphatic compounds such as benzenic compounds. These molecules exhibit a chlorinated dimethyl carbonated end.

More specifically, the present invention provides using single-crystal substrates chosen from the group comprising topaz (Al₂SiO₄(F,OH)₂) and diaspore (AlOOH).

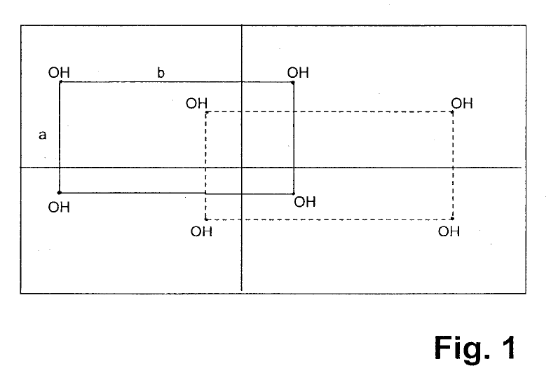

In a preferred example of embodiment, the substrate is topaz crystal. The applicants have shown that if a topaz crystal is cleaved along plane (001), hydroxyl groups regularly distributed with no crystal defect after the cleaving are obtained at the surface. FIG. 1 shows the topaz mesh in plane (001). Mesh parameters a, b, and c are a=0.465 nm, b=0.879 nm, and c=0.839 nm. The interval between hydroxyl groups OH is of 0.465 nm along axis a and of 0.44 nm along axis b. The surface area taken up by each hydroxyl group OH is of 0.2044 nm² and enables ordered grafting of molecular chains.

Chloroalkylsilanes such as dimethyloctadecylchloro-silane, C₂₀H₄₃ClSi, or dimethyldecylchlorosilane, C₁₂H₂₇ClSi, are adapted for the grafting. Trimethylchlorotin C₃H₉ClSn also allows the grafting reaction and thus enables, after reaction, having an organometallic layer R—Sn—O—, semiconductor at its surface. Simple chlorides such as tin chloride ClSn may also be made to catch to obtain a monolayer of tin. In these various cases, the catching is performed by reaction between the chloride and group hydroxyl OH and by elimination of hydrogen chloride HCl.

Except for the halogenated end, the rest of the molecule may be functionalized according to the desired applications. The molecule will comprise an element giving it a desired functional property or enabling it to connect to a molecule providing this desired functional property. Unsaturate groups (aromatic, heterocycles), ionic groups, or organometallic groups may be used. Any compound or group capable of providing specific properties to the exposed surface may be chosen. For example, groups exhibiting a positive or negative ionicity may be made to catch, to form a polarity detector. Groups capable of giving the exposed surface a hydrophilic or hydrophobic character may also be made to catch.

The catching or assembling of molecules on the substrate may be performed by putting in contact for 60 minutes the properly-cleaved topaz and a solution of the molecules to be grafted (dimethyloctadecylchlorosilane, for example) in the perfectly anhydric tetrahydrofurane (THF). The substrate is then rinsed with anhydric THF under argon and kept in a vacuum desiccator. The applicant has thus formed topaz surfaces of 1 cm² covered with octadecyl alkane chains (C₁₈) with a single-crystal bidirectional order over the entire substrate surface.

The present invention is likely to have various alterations, modifications, and improvement which will readily occur to those skilled in the art.

Like topaz, diaspore fulfills the criteria of the present invention (cleavable crystal having a cleavage plane comprising hydroxyl groups accessible at the surface, the distance between hydroxyl groups in the cleavage plane being compatible with the bulk of the molecules to be grafted). However, many cleavable minerals containing OH groups are not satisfactory. Thus, muscovite, talcum, pyrofullite are cleavable materials, but the OH groups of which are not accessible. Although amblygonite has OH groups, the mineral is not cleavable. Prussite is a cleavable mineral having OH groups in this cleavage plane, but spaced apart by too small distances to enable the chemical grafting reaction to occur.

Generally, the present invention aims at a substrate adapted to the chemical grafting of an ordered molecular monolayer, formed of a crystal, the lattice of which comprises a hydroxyl group, this crystal being cleavable so that hydroxyl groups appear in the cleavage plane, and belonging to the group comprising topaz and diaspore.

The present invention also aims at a structure comprising a substrate such as mentioned hereabove on which have been grafted molecules comprising a chlorinated, hydrocarbonated, or metallic dimethyl end.

According to an embodiment of the present invention, the grafted molecules comprise an aliphatic chain.

According to an embodiment of the present invention, the grafted molecules comprise a perfluorinated chain.

According to an embodiment of the present invention, the grafted molecules comprise an unsaturate chain.

According to an embodiment of the present invention, the grafted molecules comprise an aromatic chain.

According to an embodiment of the present invention, the grafted molecules comprise an organometallic chain.

According to an embodiment of the present invention, the grafted molecules comprise a heterocyclic group.

According to an embodiment of the present invention, desired functional groups have been fixed on the grafted molecules.

According to an embodiment of the present invention, chains of dimethyloctadecylchlorosilane in solution in tetrahydrofurane have been fixed to the substrate at room temperature.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A substrate adapted to the chemical grafting of an ordered molecular monolayer, formed of a crystal, the lattice of which comprises a hydroxyl group, this crystal being cleavable so that hydroxyl groups appear in the cleavage plane, and belonging to the group comprising topaz and diaspore.

2. A structure comprising the substrate of claim 1, on which have been grafted molecules comprising a chlorinated, hydrocarbonated, or metallic dimethyl end.

3. The structure of claim 2, wherein the grafted molecules comprise an aliphatic chain.

4. The structure of claim 2, wherein the grafted molecules comprise a perfluorinated chain.

5. The structure of claim 2, wherein the grafted molecules comprise an unsaturate chain.

6. The structure of claim 5, wherein the grafted molecules comprise an aromatic chain.

7. The structure of claim 2, wherein the grafted molecules comprise an organometallic chain.

8. The structure of any of claims 2 to 5, wherein the grafted molecules comprise a heterocyclic group.

9. The structure of claim 2, wherein desired functional groups have been fixed on the grafted molecules.

10. The substrate of claim 1, on which have been fixed at room temperature chains of dimethyloctadecylchlorosilane in solution in tetrahydrofurane.
